(19) United States
(12) Patent Application Publication
(10) Pub. No.: US 2008/0157290 A1
(43) Pub. Date: Jul. 3, 2008

(54) METHOD FOR FABRICATING SEMICONDUCTOR DEVICE

(76) Inventor: Eunjong SHIN, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/958,477

(22) Filed: Dec. 18, 2007

(30) Foreign Application Priority Data
Dec. 28, 2006 (KR) 10-2006-0135968

(51) Int. Cl. H01L 23/58; H01L 21/425

(52) U.S. Cl. 257/635; 438/514; 257/E27.111; 257/E21.473

(57) ABSTRACT

A method for fabricating a semiconductor device having a non-salicide region is provided. In one embodiment, the method includes forming a non-salicide buffer oxide layer on a substrate having an isolation layer formed therein, forming a first photoresist pattern on the non-salicide buffer oxide layer to define a first region, implanting silicon ions into the first region, removing the first photoresist pattern, forming a silicon oxide layer on the first region by performing a thermal oxidization process, forming a second photoresist pattern on the silicon oxide layer, forming a non-salicide region on an upper side of the substrate, on which the silicon oxide layer has been formed, by performing a wet etch process using the second photoresist pattern as a mask, and removing the second photoresist pattern.

### RELATED APPLICATIONS

This application claims the benefit of priority to Korean Patent Application No. 10-2006-0135968, filed on Dec. 28, 2006, the entire contents of which are incorporated herewith by reference.

### BACKGROUND

1. Technical Field

The present invention relates, in general, to a method for fabricating a semiconductor device and, more particularly, to a method for fabricating a semiconductor device having a non-self-aligned silicide (non-salicide) region divided by a self-aligned silicide (salicide) region of the semiconductor device.

2. Related Art

As well known in the art, an analog semiconductor device may include, for example, capacitors, resistors, inductors, and so on.

In particular, the resistors of the analog semiconductor device may be fabricated by performing an ion implantation process on, for example, an active region or a polysilicon layer of the analog semiconductor device, according to a resistance specification, so that the resistors may have a desired property. In certain cases, the resistors may be formed in the same process for forming a transistor of the analog semiconductor device, especially in a process for forming the active region, the polysilicon layer, etc., of the analog semiconductor device. Thus, when a resist pattern is formed, a non-salicide region may generally be formed. In certain cases, the non-salicide region may be formed by a wet etch process or a dry etch process.

FIGS. 1A and 1B are cross-sectional views illustrating a process for forming a non-salicide region through a wet etch process according to the related art.

Referring to FIG. 1A, an isolation layer 102 for electrically isolating circuit elements is formed in a P type silicon substrate 100, such as a P-type silicon substrate, through a shallow trench isolation (STI) process or the like. A non-salicide buffer oxide layer 104 is deposited on a top surface of substrate 100, in which isolation layer 102 has been formed. A photoresist pattern 106 is formed on non-salicide buffer oxide layer 104. Non-salicide buffer oxide layer 104 may be formed by, for example, a tetraethylorthosilicate (TEOS) layer having a thickness of about 900 to 1100 angstroms using a plasma-enhanced chemical vapor deposition (PE-CVD) method.

Referring to FIG. 1B, non-salicide buffer oxide layer 104 may be patterned using photoresist pattern 106 as a mask, so that portions of substrate 100 are exposed, thereby forming a non-salicide region 104a. In certain cases, non-salicide buffer oxide layer 104 may be patterned by performing a wet etch process, which uses, for example, hydrogen fluoride (HF). Further, an undercut phenomenon may occur at a lower portion of non-salicide region 104a (refer to reference numeral 108).

FIGS. 2A and 2B are cross-sectional views illustrating a process for forming a non-salicide region through a dry etch process according to the related art.

Referring to FIG. 2A, an isolation layer 202 for electrically isolating circuit elements is formed in a substrate 200, such as a P-type silicon substrate, through an STI process or the like. A non-salicide buffer oxide layer 204 is formed on a top surface of substrate 200, in which isolation layer 202 has been formed. A photoresist pattern 206 is formed on non-salicide buffer oxide layer 204. In certain cases, non-salicide buffer oxide layer 204 may comprise a TEOS layer having a thickness of about 900 to 1100 angstroms, which may be formed by using a PE-CVD method.

Referring to FIG. 2B, non-salicide buffer oxide layer 204 may be patterned or dry etched using photoresist pattern 206 as a mask, so that portions of substrate 200 are exposed, thereby forming a non-salicide region 204a. In this particular case, the undercut phenomena may not occur due to the dry etch process used for forming non-salicide region 204a, but a junction leakage and/or a gate leakage may still occur.

Further, if non-salicide region 204a is formed by using the dry etch process, as described above, the junction leakage and the gate leakage may be increased due to a plasma effect of the dry etch process. Further, a gate dielectric layer may be contaminated due to the existence of mobile charges and/or interface trap charges. Accordingly, direct current (DC) properties of the analog semiconductor device, such as a threshold voltage (Vₜₕ) shift, may be severely degraded.

### SUMMARY

In view of the above, embodiments consistent with the present invention provide a method for fabricating a semiconductor device including a non-salicide region. Embodiments consistent with the present invention further provide a method for fabricating a semiconductor device having a non-salicide region formed by using a silicon oxide layer through the implantation of silicon ions.

In one embodiment consistent with the present invention, there is provided a method for fabricating a semiconductor device. The method includes forming a non-salicide buffer oxide layer on a substrate having an isolation layer formed therein, forming a first photoresist pattern on the non-salicide buffer oxide layer to define a first region, implanting silicon ions into the first region, removing the first photoresist pattern, forming a silicon oxide layer on the first region by performing a thermal oxidization process, forming a second photoresist pattern on the silicon oxide layer, forming a non-salicide region on an upper side of the substrate, on which the silicon oxide layer has been formed, by performing a wet etch process using the second photoresist pattern as a mask, and removing the second photoresist pattern.

In another embodiment consistent with the present invention, there is provided a semiconductor device. The semiconductor device includes a substrate including an isolation layer formed therein, the substrate further including a region having silicon ions implanted therein, a non-salicide buffer oxide layer formed on the substrate, a silicon oxide layer formed over the region of the substrate.

### BRIEF DESCRIPTION OF THE DRAWINGS

The above and other features consistent with the present invention will become apparent from the following detailed description given in conjunction with the accompanying drawings, in which:

FIGS. 1A and 1B are cross-sectional views illustrating a conventional process for forming a non-salicide region through a wet etch process;

FIGS. 2A and 2B are cross-sectional views illustrating a conventional process for forming a non-salicide region through a dry etch process; and

FIGS. 3A to 3E are cross-sectional views illustrating a process for forming a non-salicide region by using a silicon oxide layer through silicon seed implantation, in accordance with an embodiment consistent with the present invention.

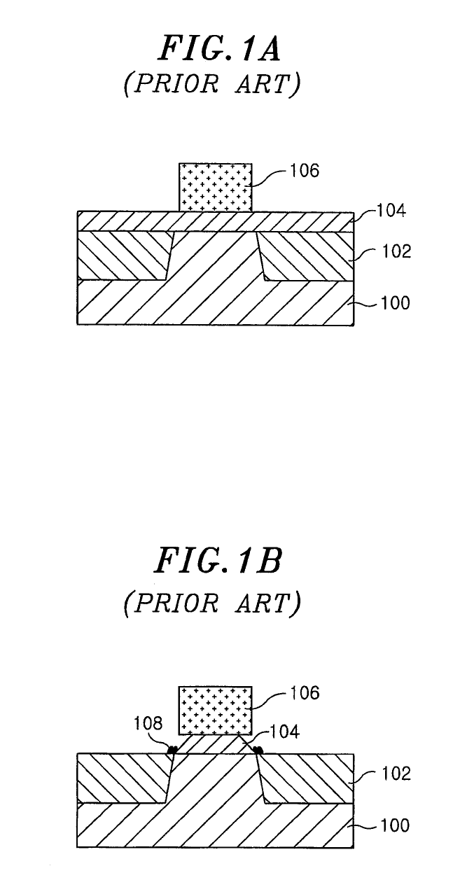

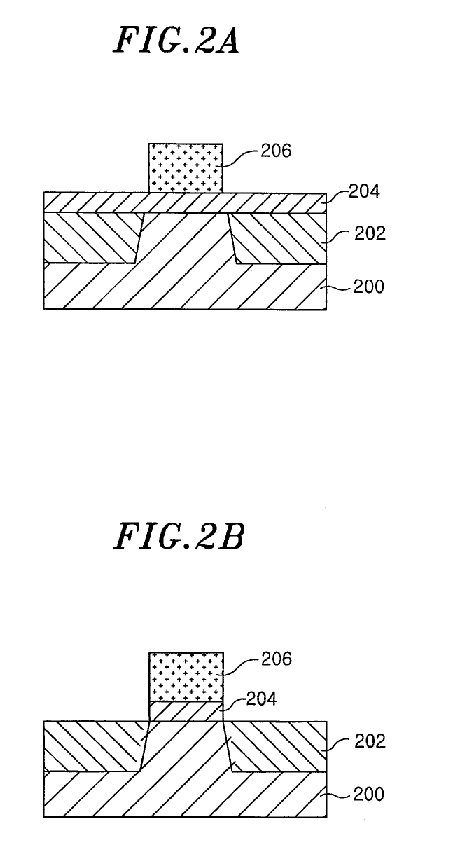

### DETAILED DESCRIPTION

Hereinafter, embodiments consistent with the present invention will be described in detail with reference to the accompanying drawings.

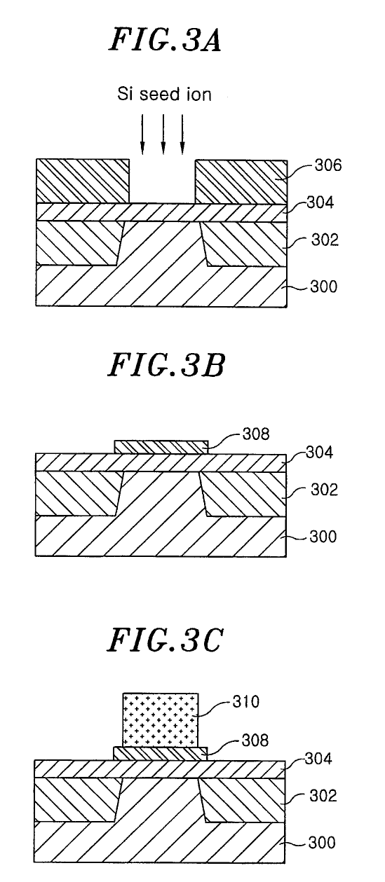

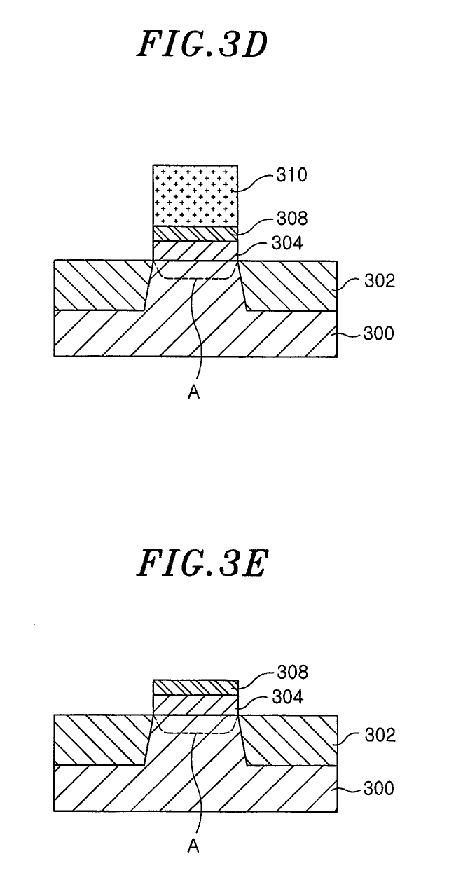

FIGS. 3A to 3E are cross-sectional views illustrating a process for forming a non-salicide region by using a silicon oxide layer through silicon seed implantation, in accordance with an embodiment consistent with the present invention.

Referring to FIG. 3A, an isolation layer 302 for electrically isolating elements is formed in a substrate 300, such as a P-type substrate, through an STI process or the like. A non-salicide buffer oxide layer 304 is formed on a top surface of substrate 300, in which isolation layer 302 has been formed. A first photoresist pattern 306 is formed on non-salicide buffer oxide layer 304. First photoresist pattern 306 may define a non-salicide region. may be implanted into the non-salicide region using first photoresist pattern 306 as a mask. In one embodiment, non-salicide buffer oxide layer 304 may comprise a TEOS layer having a thickness of about 900 to 1100 angstroms, which may be formed by using a PE-CVD method. In another embodiment, first photoresist pattern 306 may comprise a negative type photoresist.

First photoresist pattern 306 formed over substrate 300, into which the Si ions have been implanted, may be removed by using an ashing process. An oxide layer (not shown) may be formed on non-salicide buffer oxide layer 304 using a thermal oxidization process. The oxide layer may be patterned to form a silicon oxide (SiO₂) layer 308 as shown in FIG. 3B. The thermal oxidization process may be performed by using, for example, a nitrogen gas (N₂) at a temperature ranging from about 550 to about 650 degrees Celsius. In one embodiment, silicon oxide layer 308 may be formed to have an area greater than that of the non-salicide region.

Referring to FIG. 3C, a second photoresist pattern 310 is formed over substrate 300, on which silicon oxide layer 308 has been formed. In one embodiment, second photoresist pattern 310 may comprise a negative type photoresist.

Referring to FIG. 3D, silicon oxide layer 308 and non-salicide buffer oxide layer 304 may be wet etched using second photoresist pattern 310 as a mask, so that portions of substrate 300 are exposed, thereby forming a non-salicide region A. In one embodiment, the wet etch process may be performed by using a wet chemical, such as HF.

Referring to FIG. 3E, second photoresist pattern 310 may be removed by using an ashing process.

As described above, when forming non-salicide region A on substrate 300, Si ions may be implanted into non-salicide region A. Further, silicon oxide layer 308 may be formed and patterned through a wet etch process, thereby forming non-salicide region A. Accordingly, undercut phenomena due to the wet etch process and plasma damages due to the dry etch process may be prevented from occurring. Therefore, the performance of the semiconductor device may be improved.

While the present invention has been described in detail with respect to specific embodiments, it is to be understood by those skilled in the art that various changes and modifications may be made without departing from the spirit and scope consistent with the present invention as defined in the following claims.

What is claimed is:

1. A method for fabricating a semiconductor device, comprising:
forming a non-salicide buffer oxide layer on a substrate having an isolation layer formed therein;
forming a first photoresist pattern on the non-salicide buffer oxide layer to define a first region;
implanting silicon ions into the first region;
removing the first photoresist pattern;
forming a silicon oxide layer on the first region by performing a thermal oxidization process;
forming a second photoresist pattern on the silicon oxide layer;
forming a non-salicide region on an upper side of the substrate, on which the silicon oxide layer has been formed, by performing a wet etch process using the second photoresist pattern as a mask; and
removing the second photoresist pattern.

2. The method of claim 1, wherein the thermal oxidization process is performed by using a nitrogen gas.

3. The method of claim 2, wherein the thermal oxidization process is performed at a temperature ranging from about 550 to about 650 degrees Celsius.

4. The method of claim 1, wherein forming the silicon oxide layer on the first region comprises forming the silicon oxide layer to have an area greater than that of the non-salicide region.

5. The method of claim 1, wherein the wet etch process is performed by employing hydrogen fluoride (HF).

6. The method of claim 1, wherein the first photoresist pattern comprises a negative type photoresist, and the second photoresist pattern comprises a negative type photoresist.

7. A semiconductor device, comprising:
a substrate including an isolation layer formed therein, the substrate further including a region having silicon ions implanted therein;
a non-salicide buffer oxide layer formed on the substrate;
a silicon oxide layer formed over the region of the substrate.
